(19) United States
(12) Patent Application Publication
(10) Pub. No.: US 2007/0181871 A1
(43) Pub. Date: Aug. 9, 2007

(54) ORGANIC THIN FILM TRANSISTOR USING ULTRA-THIN METAL OXIDE AS GATE DIELECTRIC AND FABRICATION METHOD THEREOF

(76) Inventors: Chung Kun Song, Busan (KR); Kang Dae Kim, Busan (KR); Gi Seong Ryu, Busan (KR); Yong Xian Xu, Busan (KR); Kwang Hyun Kim, Busan (KR); Myung Won Lee, Busan (KR)

Correspondence Address: IPLA P.A., 3580 WILSHIRE BLVD., 17TH FLOOR, LOS ANGELES, CA, 90010, US

(21) Appl. No.: 11/279,850

(22) Filed: Apr. 14, 2006

(30) Foreign Application Priority Data
Feb. 6, 2006 (KR) 10-2006-0010991

(51) Int. Cl. H01L 29/08; H01L 35/24; H01L 51/00

(52) U.S. Cl. 257/40

(57) ABSTRACT

The present invention provides a low-voltage organic thin film transistor having a gate dielectric layer of ultra-thin metal oxide self-grown on a metal gate electrode by O₂ plasma process. The metal gate electrode is deposited on a plastic or glass substrate. By directly oxidizing the gate electrode by using O₂ plasma process, the gate dielectric layer of metal oxide is formed with a thickness of several nanometers on the gate electrode. The organic semiconductor layer is deposited on the gate dielectric layer, and source/drain electrodes are formed on the organic semiconductor layer. Before the organic semiconductor layer is formed, an organic molecular monolayer may be formed on the gate dielectric layer by using molecular self-assembly technique. The gate dielectric layer may be formed at room temperature to about 100° C.

### BACKGROUND OF THE INVENTION

1. Field of the Invention

The present invention relates generally to organic thin film transistor (OTFT) technology and, more particularly, to a low-voltage OTFT having a gate dielectric layer of ultra-thin metal oxide formed from direct oxidation of a metal gate electrode in O₂ plasma process.

2. Description of the Related Art

In these days organic semiconductor such as pentacene has been widely studied. Organic semiconductor may be produced by various synthesis ways and easily formed in the shape of fiber or film. Organic semiconductor may have good flexibility, good conductivity, and relatively low cost of production. Thanks to these advantages, organic semiconductor is studied as new electronic materials in wide areas including electronic devices and optical devices.

The OTFT employs organic semiconductor for semiconductor active regions in comparison with conventional silicon TFT using amorphous silicon. The OTFT is very similar in structure to conventional silicon TFT, but has merits in fabrication such as simpler processes and lower cost. For such reasons, new attempts continue today so as to apply OTFT technology to advanced electronic applications including flexible displays, RFID (radio frequency identification), and any other portable devices.

Modern OTFT technology may, however, have some technical problems to be solved. One of them is that new alternative process is needed to produce a gate dielectric layer at lower temperature. Silicon oxide or silicon nitride, typically used as the gate dielectric layer, may be formed at higher temperature, thus being not applicable to a glass or plastic substrate requiring low-temperature process.

Another problem with the existing OTFT is that an operating voltage should be reduced. Low power consumption is prerequisite to applications such as flexible displays and RFID, however the operating voltage of the OTFT often exceeds 20V. This is due to a relatively thick gate dielectric layer, which commonly reaches 100 nm or more.

Various approaches to solve these problems have been introduced in the art. For example, U.S. Pat. No. 6,207,472 discloses that a gate dielectric layer is formed of Ta₂O₃, V₂O₃, TiO₂, etc. at 25˜150° C. by using sputtering, spinning, etc. In other case, Korean Published Application No. 2005-31858 discloses that an Al₂O₃ gate dielectric layer is deposited by sputtering at room temperature to about 100° C. In another case, Japanese Published Application Nos. 2003-258260 and 2003-258261 disclose that a gate electrode of Ta, Al, etc. is anodized to form a gate dielectric layer.

Unfortunately, although these conventional techniques provide their own ways of forming metal oxide as a gate dielectric layer of the OTFT at relatively low temperature, they fail to suggest a way of reducing the thickness of the gate dielectric layer. Gate dielectric thickness in U.S. Pat. No. 6,207,472 is in the range of 0.5 μm. In Korean Published Application No. 2005-31858, the thickness is between 61 nm and 450 nm. In Japanese Published Application Nos. 2003-258260 and 2003-258261, the thickness is described as 85.64 nm, for example.

On the other hand, researches to realize a thinner gate dielectric layer have been continuously carried out in the art. For example, a paper, “Low-voltage organic transistors with an amorphous molecular gate dielectric, Marcus Halik et al., Nature, vol. 431, 2004, pp. 963-966” teaches a 2.5 nm-thick molecular self-assembled monolayer (SAM) gate dielectric on a heavily doped silicon substrate. However, this may not be available since there is no plan to electrically isolate discrete devices under the circumstances the heavily doped silicon substrate is used for gate electrodes.

Another paper, “One volt organic transistor, L. A. Majewski et al., Adv. Mater. 2005, 17, No. 2, pp. 192-196” proposes anodization of metal to form metal oxide with a thickness of several nanometers as a gate dielectric layer. However, this may lack usability since anodization, a kind of wet process, may often invite an unfavorable peeling of metal.

It is therefore required in the art to develop an advanced organic thin film transistor that allows forming an ultra-thin gate dielectric layer in low-temperature process and further permits a low-voltage operation. It is also required to develop an advanced organic thin film transistor that enables IC fabrication and thus is available for flexible displays, RFID, etc.

### SUMMARY OF THE INVENTION

Exemplary, non-limiting embodiments of the present invention provide an organic thin film transistor, which comprises a substrate, a gate electrode formed on the substrate and made of metal that can be oxidized, an ultra-thin gate dielectric layer made of metal oxide self-grown on the gate electrode by O₂ plasma process, an organic semiconductor layer formed on the gate dielectric layer, and source/drain electrodes formed on the organic semiconductor layer and spaced apart from each other.

According to one exemplary embodiment of the present invention, the organic thin film transistor may further comprise an organic molecular monolayer, which is interposed between the gate dielectric layer and the organic semiconductor layer and is formed by molecular self-assembly technique. The organic molecular monolayer may be made of (Benzyloxy)alkyltrimethoxysilane, for example.

Exemplary, non-limiting embodiments of the present invention further provide a method of fabricating an organic thin film transistor, the method comprising depositing a gate electrode with pattern on a substrate, the gate electrode being made of metal capable of being oxidized; directly oxidizing the gate electrode by using O₂ plasma process such that an ultra-thin gate dielectric layer is formed of metal oxide self-grown on the gate electrode; depositing an organic semiconductor layer on the gate dielectric layer; and forming source/drain electrodes on the organic semiconductor layer such that the source/drain electrodes are spaced apart from each other.

According to another exemplary embodiment of the invention, the method may further comprise, before the depositing of the organic semiconductor layer, forming an organic molecular monolayer on the gate dielectric layer by using molecular self-assembly technique.

In still another exemplary embodiment of the invention, the substrate may be made of plastic or glass. Additionally, the gate electrode may be made of aluminum, and thus the gate dielectric layer may be aluminum oxide. Moreover, the gate dielectric layer may be formed at room temperature to about 100° C. Also, the gate dielectric layer may have a thickness of several nanometers.

### BRIEF DESCRIPTION OF THE DRAWINGS

FIG. 1 is a cross-sectional view showing an organic thin film transistor in accordance with an exemplary embodiment of the present invention.

FIG. 2 is a cross-sectional view showing an organic thin film transistor in accordance with another exemplary embodiment of the present invention.

FIG. 3 shows a chemical structure of an organic molecular monolayer shown in FIG. 2.

FIGS. 4A to 4D are cross-sectional views showing a fabrication method of the organic thin film transistor shown in FIG. 1.

FIG. 5 is a TEM photograph showing an aluminum oxide layer of an experimental example of the present invention.

FIG. 6 is a graph showing the I-V characteristic curve of the aluminum oxide layer shown in FIG. 5.

FIG. 7 is a graph showing the breakdown voltage curve of the aluminum oxide layer shown in FIG. 5.

FIG. 8 is a graph showing the capacitance curve of the aluminum oxide layer shown in FIG. 5.

FIGS. 9A and 9B are graphs respectively showing I_{DS}-V_{GS}, I_{DS}-V_{DS} characteristic curves of the OTFT with the aluminum oxide layer shown in FIG. 5.

### DETAILED DESCRIPTION OF EXEMPLARY EMBODIMENTS OF THE INVENTION

Exemplary, non-limiting embodiments of the present invention will now be described more fully hereinafter with reference to the accompanying drawings. This invention may, however, be embodied in many different forms and should not be construed as limited to the exemplary embodiments set forth herein. Rather, the disclosed embodiments are provided so that this disclosure will be thorough and complete, and will fully convey the scope of the invention to those skilled in the art. The principles and features of this invention may be employed in varied and numerous embodiments without departing from the scope of the invention.

It is noted that well-known structures and processes are not described or illustrated in detail to avoid obscuring the essence of the present invention. It is also noted that the figures are not drawn to scale. Rather, for simplicity and clarity of illustration, the dimensions of some of the elements are exaggerated relative to other elements. Like reference numerals are used for like and corresponding parts of the various drawings.

Organic Thin Film Transistor (OTFT)

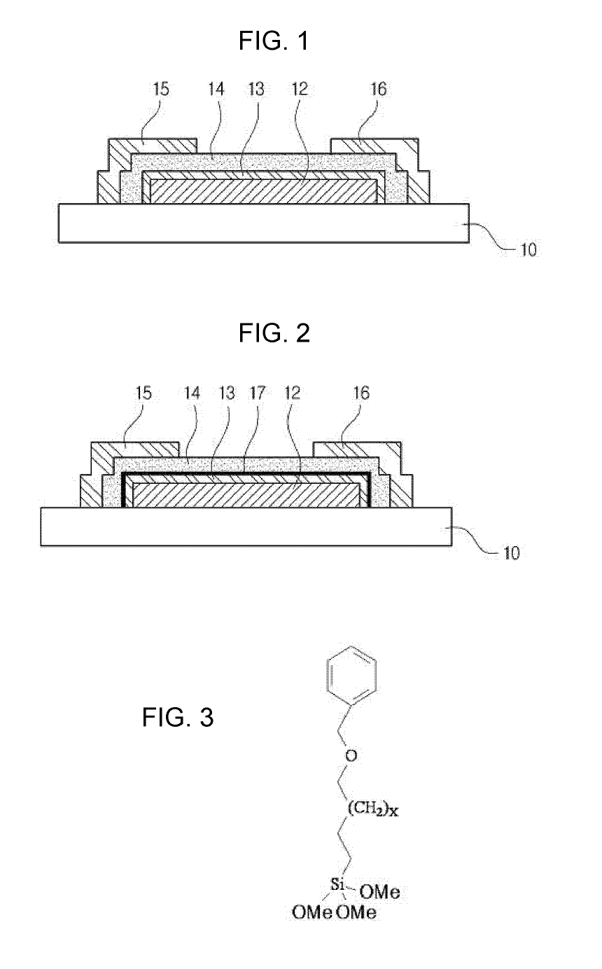

FIG. 1 shows, in a cross-sectional view, an organic thin film transistor in accordance with an exemplary embodiment of the present invention.

Referring to FIG. 1, a gate electrode 12 is formed on a substrate 10 made of, for example, plastic or glass. A thin gate dielectric layer 13 is grown on surfaces of the gate electrode 12. The gate electrode 12 is made of metal, which can be oxidized inherently, such as aluminum (Al), titanium (Ti), tantalum (Ta), etc, and the gate dielectric layer 13 is self-grown by directly oxidizing the metal gate electrode 12. So the gate dielectric layer 13 is metal oxide such as aluminum oxide (Al₂O₃), titanium oxide (TiO₂), tantalum oxide (Ta₂O₅), etc. Particularly, the gate dielectric layer 13 of metal oxide is created in low-temperature process and has a thickness of several nanometers.

An organic semiconductor layer 14, such as pentacene layer, is formed on the gate dielectric layer 13. A source electrode 15 and a drain electrode 16 are then formed on the organic semiconductor layer 14, being spaced apart from each other. The source and drain electrodes 15 and 16 are made of metal such as gold (Au) or aluminum (Al).

As shown in FIG. 2, the OTFT of the invention may further include an organic molecular monolayer 17 interposed between the gate dielectric layer 13 and the organic semiconductor layer 14. The organic molecular monolayer 17 can be formed by molecular self-assembly technique as well known in the art. The organic molecular monolayer 17 may change surfaces of the gate dielectric layer 13 from hydrophillicity to hydrophoicity, and thus may facilitate relatively dense formation of the organic semiconductor layer 14. This may improve electrical characteristics of the OTFT, such as mobility, off state current, etc.

Appropriate material of the organic molecular monolayer 17 may be (Benzyloxy)alkyltrimethoxysilane, for example, a chemical structure of which is shown in FIG. 3. Referring to FIG. 3, the chemical structure of the organic molecular monolayer 17 is composed of a head part, an intermediate part, and a tail part. The head part has a low surface energy with the organic semiconductor layer 14. The intermediate part has an alkyl chain organization that exhibits high dielectric properties. The tail part has silane structure that may allow molecular self-assembled monolayers (SAM).

Fabrication Method of OTFT

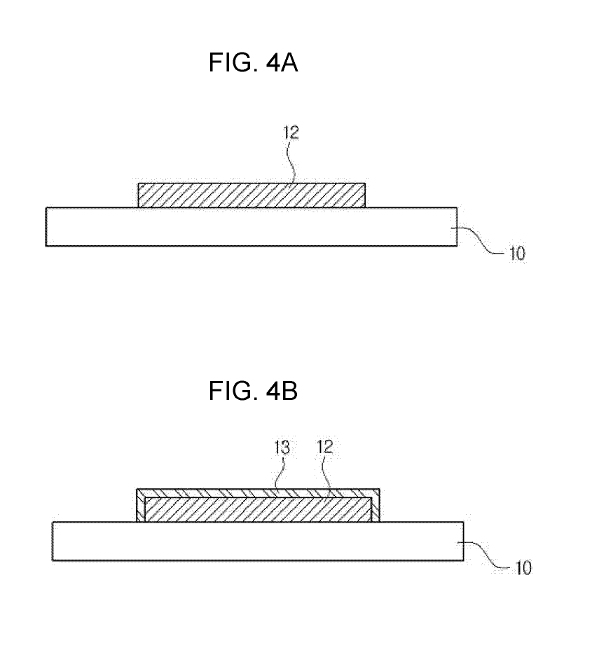

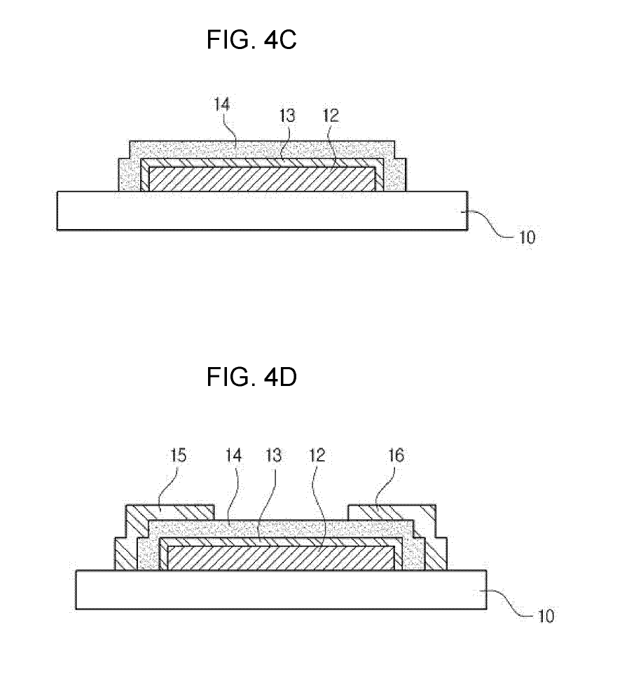

A method of fabricating the aforementioned OTFT device will be described hereinafter. From the following descriptions of the fabrication, the structure of the OTFT will also become clearer. FIGS. 4A to 4D are cross-sectional views showing a fabrication method of the OTFT shown in FIG. 1.

Referring to FIG. 4A, the gate electrode 12 is deposited and patterned on the plastic or glass substrate 10. The gate electrode 12 may be made of aluminum, for example. However, the materials of the gate electrode 12 are not limited to specific kinds of metal. Deposition of the metal gate electrode 12 may use thermal evaporation, e-beam evaporation, sputtering, or other suitable technique as well known in the art. Patterning of the metal gate electrode 12 may be accomplished by using well-known technique such as shadow mask or photolithography.

Next, as shown in FIG. 4B, the gate dielectric layer 13 is self-grown on the gate electrode 12 by O₂ plasma process. Specifically, the metal gate electrode 12 is oxidized in O₂ plasma process, so that the gate dielectric layer 13 is formed of metal oxide with an ultra-thin thickness of several nanometers (e.g., 5 nm) at low temperature (i.e., room temperature to about 100° C.). For example, O₂ plasma process may be implemented for 10 minutes under an O₂ flow ratio of about 10 sccm, a pressure of about 30 mtorr, and a power of about 50 W.

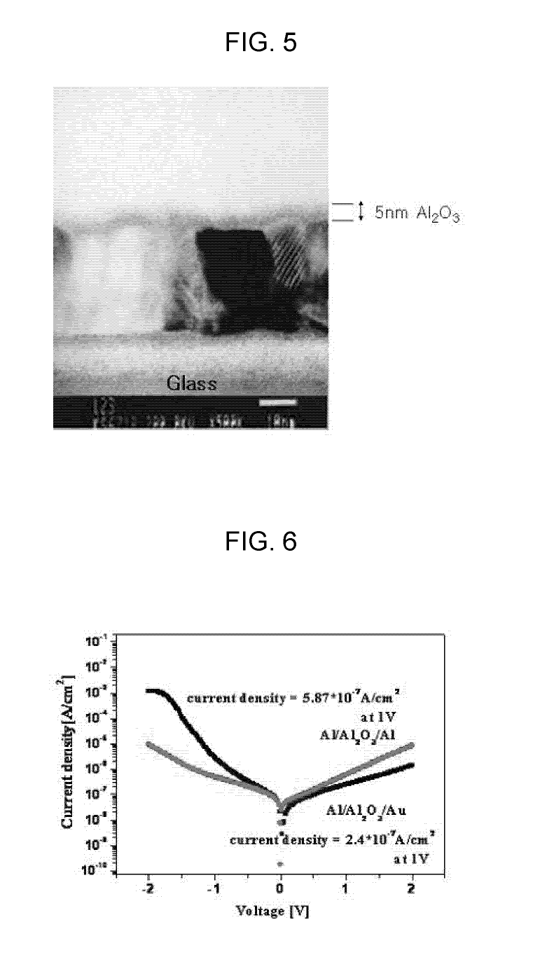

FIG. 5 shows, in a TEM photograph, an aluminum oxide layer formed as the gate dielectric layer by O₂ plasma process performed under the above conditions. In FIG. 5, the aluminum oxide layer on the gate electrode measured about 5 nm thick. It will be appreciated that the above conditions in O₂ plasma process are exemplary only and not to be considered as a limitation of exemplary embodiments of the present invention.

Direct oxidation of the metal gate electrode 12, which uses O₂ plasma process available for low temperature, enables the substrate 10 to employ plastic or glass that is not suitable for high-temperature process. Moreover, direct oxidation using O₂ plasma process decreases the thickness of the gate dielectric layer 13 to several nanometers, so that the OTFT can operate at a low voltage less than 2V. Additionally, since the gate dielectric layer 13 is self-grown on the gate electrode 12 already patterned, it is not necessary to perform additional isolation process for separating discrete devices.

Next, as shown in FIG. 4C, the organic semiconductor layer 14 is deposited on the gate dielectric layer 13 by using thermal evaporation, for example. The organic semiconductor layer 14 may use, but not limited to, pentacene. Before forming the organic semiconductor layer 14, the above-discussed organic molecular monolayer, 17 in FIG. 2, may be optionally formed on the gate dielectric layer 13.

Finally, as shown in FIG. 4D, the source electrode 15 and the drain electrode 16 are formed on the organic semiconductor layer 14, being spaced apart from each other.

### EXPERIMENTAL EXAMPLE 1

### Electrical Characteristics of Aluminum Oxide

To investigate electrical characteristics of the aluminum oxide layer shown in FIG. 5, I-V (current-voltage) and C-V (capacitance-voltage) measuring experiments were carried out by using suitable equipment, HP4155A and HP4280A, respectively. FIGS. 6 to 8, obtained from such experiments, show the I-V characteristic curve, the breakdown voltage curve, and the capacitance curve of the aluminum oxide layer, respectively.

FIG. 6 plots the I-V curves in an Al/Al₂O₃/Al structure and in an Al/Al₂O₃/Au structure. The result of FIG. 6 shows different leakage current densities in both structures. For example, the Al/Al₂O₃/Al structure exhibits relatively high current density of 5.87×10⁻⁷A/cm² at 1V, whereas the Al/Al₂O₃/Au structure does relatively low current density of 2.4 ×10⁻⁷A/cm² at 1V. This may be caused by a difference in work function between aluminum and gold.

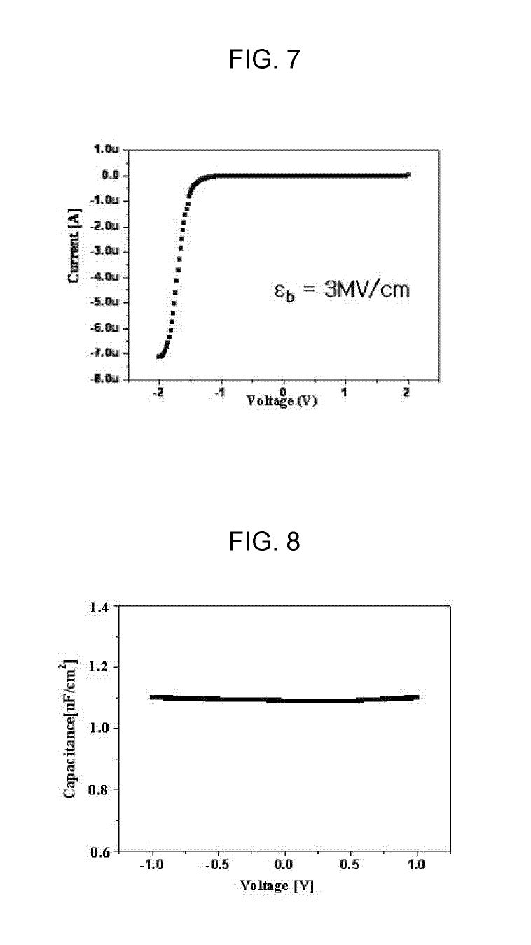

As depicted in FIG. 7, the breakdown voltage of the aluminum oxide layer measured about 3 MV/cm in the Al/Al₂O₃/Au structure.

FIG. 8 shows the C-V curve in the Al/Al₂O₃/Al structure, in which the capacitance of the aluminum oxide layer measured about 1.1 μF/cm². Considering the thickness of the aluminum oxide layer shown in FIG. 5, the dielectric constant was calculated at about 6.2.

### EXPERIMENTAL EXAMPLE 2

### Electrical Characteristics of Pentacene OTFT

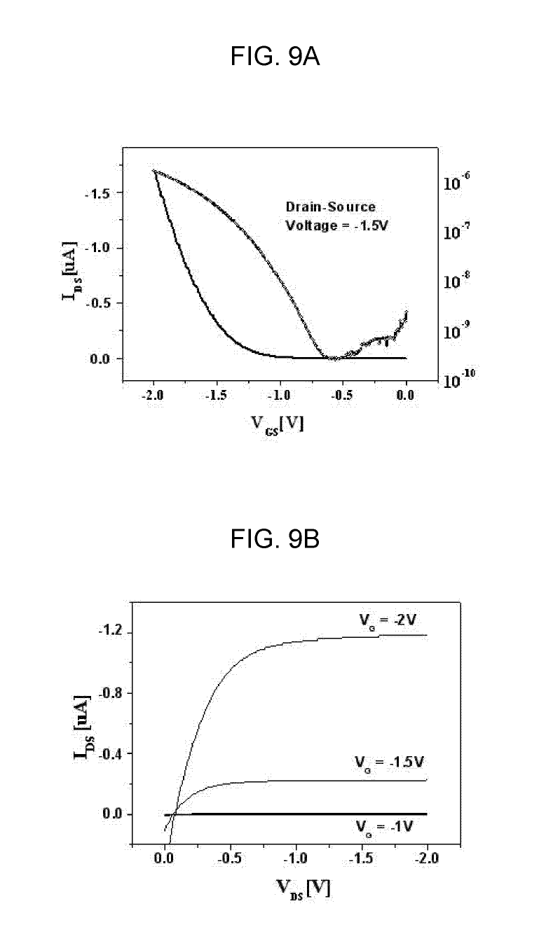

FIGS. 9A and 9B respectively show I_{DS}-V_{GS}, I_{DS}-V_{DS} characteristic curves of the pentacene OTFT having the aluminum oxide layer shown in FIG. 5. Electrical characteristics thereof are shown in the following Table 1.

TABLE 1

| | On/Off | Threshold | Subthreshold | Off State |
|---|---|---|---|---|
| Mobility | Current | Voltage | Slope | Current |
| (cm²/V · sec) | Ratio(Iₒₙ/I_{off}) | (V) | (V/dec) | (pA/μm) |
| 0.1 | 6.3 × 10³ | −1.13 | 0.206 | 0.25 |

As shown in Table 1, the OTFT has a mobility of 0.1 cm²/V·sec, an on/off current ratio (Iₒₙ/I_{off}) of 6.3×10³, a threshold voltage (Vₜ) of −1.13V, a subthreshold slope of 0.206V/dec, and an off state current of 0.25 pA/μm. Moreover, at V_{GS}=−2V, a drain/source saturation voltage (V_{DS}, ₛₐₜ) measured −0.7V, and thus confirmed low-voltage operation of the OTFT.

As fully discussed hereinbefore, the low-voltage OTFT with ultra-thin metal oxide gate dielectric of the present invention has many advantages in comparison with conventional OTFTs, as follows.

First, the OTFT of the invention can be fabricated by low-temperature process ranging from room temperature to about 100° C. So the OTFT of the invention can employ a plastic or glass substrate not suitable for high-temperature process.

Second, the OTFT of the invention has ultra-thin metal oxide as the gate dielectric layer, so operating voltage thereof can be significantly reduced and thus the OTFT is available for flexible displays, RFID, etc.

Third, the OTFT of the invention requires no process of patterning the gate dielectric layer for isolation. So related fabrication processes are made simpler.

Fourth, to further improve electrical characteristics, the OTFT of the invention may also have an organic molecular monolayer self-assembled between the gate dielectric layer and the organic semiconductor layer.

While this invention has been particularly shown and described with reference to exemplary embodiments thereof, it will be understood by those skilled in the art that various changes in form and details may be made therein without departing from the spirit and scope of the invention as defined by the appended claims.

What is claimed is:

1. An organic thin film transistor comprising:
a substrate;
a gate electrode formed on the substrate, wherein the gate electrode is made of metal that can be oxidized;
an ultra-thin gate dielectric layer formed on the gate electrode, wherein the gate dielectric layer is made of metal oxide that is self-grown on the gate electrode by O₂ plasma process;
an organic semiconductor layer formed on the gate dielectric layer; and
source/drain electrodes formed on the organic semiconductor layer, wherein the source/drain electrodes are spaced apart from each other.

2. The organic thin film transistor of claim 1, wherein the substrate is made of plastic or glass.

3. The organic thin film transistor of claim 1, wherein the gate electrode is made of aluminum and the gate dielectric layer is aluminum oxide.

4. The organic thin film transistor of claim 1, wherein the gate dielectric layer is formed at room temperature to about 100° C.

5. The organic thin film transistor of claim 1, wherein the gate dielectric layer has a thickness of several nanometers.

6. The organic thin film transistor of claim 1, further comprising:
an organic molecular monolayer interposed between the gate dielectric layer and the organic semiconductor layer, wherein the organic molecular monolayer is formed by molecular self-assembly technique.

7. The organic thin film transistor of claim 6, wherein the organic molecular monolayer is made of (Benzyloxy)alkyltrimethoxysilane.

8. A method of fabricating an organic thin film transistor, the method comprising:
depositing a gate electrode with pattern on a substrate, wherein the gate electrode is made of metal capable of being oxidized;
directly oxidizing the gate electrode by using O₂ plasma process such that an ultra-thin gate dielectric layer is formed of metal oxide self-grown on the gate electrode;
depositing an organic semiconductor layer on the gate dielectric layer; and
forming source/drain electrodes on the organic semiconductor layer such that the source/drain electrodes are spaced apart from each other.

9. The method of claim 8, wherein the substrate is made of plastic or glass.

10. The method of claim 8, wherein the gate electrode is made of aluminum and the gate dielectric layer is aluminum oxide.

11. The method of claim 8, wherein the gate dielectric layer is formed at room temperature to about 100° C.

12. The method of claim 8, wherein the gate dielectric layer has a thickness of several nanometers.

13. The method of claim 8, further comprising:
before the depositing of the organic semiconductor layer, forming an organic molecular monolayer on the gate dielectric layer by using molecular self-assembly technique.

14. The method of claim 13, wherein the organic molecular monolayer is made of (Benzyloxy)alkyltrimethoxysilane.
